(19) United States
(12) Patent Application Publication
(10) Pub. No.: US 2008/0129193 A1
(43) Pub. Date: Jun. 5, 2008

(54) LIGHT EMITTING DEVICE AND PRODUCING METHOD THEREOF

(76) Inventors: Yoshiyuki ASABE, Fukushima-ken (JP); Takashi NITTA, Fukushima-ken (JP); Masashi SAITO, Fukushima-ken (JP)

Correspondence Address: BRINKS HOFER GILSON & LIONE, P.O. BOX 10395, CHICAGO, IL, 60610, US

(21) Appl. No.: 11/942,958

(22) Filed: Nov. 20, 2007

(30) Foreign Application Priority Data
Nov. 22, 2006 (JP) 2006-315943

(51) Int. Cl. H01J 1/62; H01L 51/56

(52) U.S. Cl. 313/504; 438/99; 257/E51.019

(57) ABSTRACT

A light emitting device and a producing method thereof are provided. The light emitting device is configured such that a transparent electrode layer, an organic light emitting layer and a counter electrode layer are laminated in this order on a transparent substrate, in which the transparent electrode layer is formed of mesh-like metal material and a transparent conductive polymer. The producing method includes: (a) printing a solution in which metal particles are dispersed in a solvent in a mesh shape on a transparent substrate so as to form a mesh-like metal layer on the transparent substrate; (b) forming a transparent conductive polymer layer on the mesh-like metal layer; (c) forming an organic light emitting layer on the transparent conductive polymer layer; and (d) forming a counter electrode layer on the organic light emitting layer.

### RELATED APPLICATIONS

This application claims the benefit of priority under 35 U.S.C. §119 to Japanese Patent Application No. 2006-315943 filed Nov. 22, 2006, the entire contents of which are hereby incorporated by reference in its entirety.

### BACKGROUND

1. Field of the Invention

The present invention relates to a light emitting device having an organic light emitting layer, and more particularly, to a light emitting device having an organic light emitting layer disposed between an anode and a cathode. That is, the present invention relates to a light emitting device using a so-called organic EL element and a producing method thereof.

2. Description of the Related Art

Light emitting devices using an organic light emitting material, such as an organic light emitting layer, basically have a sandwich structure in which the organic light emitting layer is sandwiched between two electrode layers, a cathode layer and an anode layer. In such light emitting devices, electrons and holes are injected into the light emitting layer from the cathode layer and the anode layer, respectively, and the injected electrons and holes are recombined with each other to emit light.

Organic light emitting materials are broadly classified into low-molecular light emitting materials such as an aluminum quinolinol complex and high-molecular light emitting materials such as polyphenylenevinylene. The low-molecular light emitting materials are deposited to form light emitting elements by a vacuum deposition method. The high-molecular light emitting materials can be melted in a solvent and then printed onto light emitting elements by a printing technology such as a coating method or an inkjet printing method. Therefore, it is possible to decrease the production cost and to use a glass substrate and a resin sheet as a substrate.

JP-A-10-077467 (Patent Document 1) discloses a light emitting device using a high-molecular light emitting material. JP-A-11-273859 (Patent Document 2) discloses an organic light emitting device produced by applying a solution of a low-molecular light emitting material.

In the light emitting devices using organic light emitting materials as the organic light emitting layer, in order to output light emitted from the organic light emitting layer to the outside, one electrode layer (anode) needs to be a transparent electrode layer. In the past, as described in Patent Documents 1 or 2, conductive metal oxides such as indium tin oxides (ITO), tin oxides (SnO₂) or zinc oxides (ZnO), or an organic transparent conductive film using a transparent conductive polymer were used as the transparent electrode layer.

Since metal oxides such as ITO have a high conductivity and an excellent transparency, the light emitting device can emit a sufficient amount of light. However, such materials as ITO are produced through vacuum deposition or sputtering, increasing the production cost. In the case of printing an organic light emitting layer using a high-molecular light emitting material before or after forming an anode layer, the printing is problematic because the printing should be performed at the atmospheric pressure. Moreover, the anode layer is not likely to closely adhere to the organic light emitting layer and is easily peeled off from the organic light emitting layer, producing dark spots.

In the case of using the light emitting device having the organic light emitting layer as an illuminator in a keypad of a cellular phone, the anode layer needs to have excellent properties for flexibility and mechanical strength. However, since metal oxides such as ITO are hard and brittle, such materials are poor in flexibility and mechanical strength. Therefore, it is difficult to utilize the light emitting device having the organic light emitting layer in the keypad of a cellular phone that needs to have a sufficient flexibility or a sufficient mechanical strength, narrowing applicability of the light emitting device.

On the other hand, an organic transparent electrode layer using a conductive polymer such as PEDOT (polyethylene dioxythiophene) can be easily produced and is flexible. However, since the layer has a low conductivity, the light emitting device cannot emit a sufficient amount of light.

Alternatively, a transparent electrode layer may have a laminated structure in which metal oxides such as ITO are deposited on or below an organic transparent electrode layer. However, since the metal oxides such as ITO are hard and brittle, they are weak to an external mechanical force.

### SUMMARY

The present invention provides a light emitting device using an organic light emitting layer having a transparent electrode (anode) layer having excellent flexibility and mechanical strength properties. The present invention also provides a method of producing the light emitting device.

According to a first aspect of the present disclosure, there is provided a light emitting device in which a transparent electrode layer, an organic light emitting layer and a counter electrode layer are laminated in this order on a transparent substrate, wherein the transparent electrode layer is formed of mesh-like metal material and a transparent conductive polymer.

According to a second aspect of the present disclosure, there is provided a light emitting device in which a lower electrode layer, an organic light emitting layer and a transparent electrode layer are laminated in this order on a substrate, wherein the transparent electrode layer is formed of mesh-like metal material and a transparent conductive polymer.

Since the transparent electrode layer is formed of mesh-like metal material and a transparent conductive polymer, the light emitting device of the present disclosure has flexibility and a mechanical strength. Therefore, the light emitting device of the present disclosure can be applied, for example, to a contact film illuminator in a keypad of a cellular phone that needs to have flexibility and a mechanical strength.

According to a third aspect of the present disclosure, there is provided a method of producing a light emitting device using an organic light emitting layer, the method including the steps of: (a) printing a solution in which metal particles are dispersed in a solvent in a mesh shape on a transparent substrate so as to form a mesh-like metal layer on the transparent substrate; (b) forming a transparent conductive polymer layer on the mesh-like metal layer; (c) forming an organic light emitting layer on the transparent conductive polymer layer; and (d) forming a counter electrode layer on the organic light emitting layer.

According to a fourth further aspect of the present disclosure, there is provided a method of producing a light emitting device using an organic light emitting layer, the method including the steps of: (a) forming a lower electrode layer; (b) forming an organic light emitting layer on the lower electrode layer; (c) forming a transparent conductive polymer layer on the organic light emitting layer; and (d) printing a solution in which metal particles are dispersed in a solvent in a mesh shape on the transparent conductive polymer layer so as to form a mesh-like metal layer on the transparent conductive polymer layer.

In the third aspect of the invention, the method may further include (e) instead of step (a), applying and drying nano-sized metal particles on a transparent substrate so as to form a mesh-like metal layer on the transparent substrate.

In the fourth aspect of the invention, the method may further include (e) instead of step (d), applying and drying nano-sized metal particles on the transparent conductive polymer layer so as to form a mesh-like metal layer on the transparent conductive polymer layer.

According to the light emitting device of the present invention, since the transparent electrode layer is formed of mesh-like metal material and a transparent conductive polymer, the light emitting device of the present invention has flexibility and a mechanical strength. Therefore, the light emitting device of the present invention can be applied, for example, to a contact film illuminator in a keypad of a cellular phone that needs to have flexibility and a mechanical strength. Since the transparent electrode layer is formed of the mesh-like metal, the light emitting device of the present invention is excellent in conductivity and can provide light emission with high efficiency and intensity. In addition, since the metal can be formed in a simple manner by using a printing technology or self-organization of nano-sized particles, it is possible to simplify the production process and to produce the light emitting device at low cost.

Other systems, methods, features, and advantages of the invention will be, or will become, apparent to one with skill in the art upon examination of the following figures and detailed description. It is intended that all such additional systems, methods, features, and advantages be included within this description.

### BRIEF DESCRIPTION OF THE DRAWINGS

The components in the figures are not necessarily to scale, emphasis instead being placed upon illustrating the principles of the present invention. Moreover, in the figures, like referenced numerals designate corresponding parts throughout the different views.

FIG. 1 is a perspective view of a light emitting device according to a first embodiment of the present disclosure.

FIG. 2 is a sectional view taken along the line I-I line of FIG. 1, illustrating the light emitting device of the first embodiment.

FIG. 3 is a perspective view of a transparent electrode layer of the present disclosure.

FIG. 4 is schematic view of a mesh-like metal layer obtained by self-organization of colloidal nano-sized metal particles.

FIG. 5 is a sectional view taken along the line I-I line of FIG. 1, illustrating a light emitting device according to a second embodiment of the present disclosure.

FIG. 6 is a perspective view of a light emitting device according to a third embodiment of the present disclosure.

FIG. 7 is a sectional view taken along the line II-II of FIG. 6, illustrating the light emitting device of the third embodiment.

FIG. 8 is a sectional view illustrating a test method for evaluating flexibility of a light emitting device.

### DESCRIPTION OF THE EMBODIMENTS

Exemplary embodiments may be better understood with reference to the drawings, but these examples are not intended to be of a limiting nature. Like numbered elements in the same or different drawings perform equivalent functions.

### First Embodiment

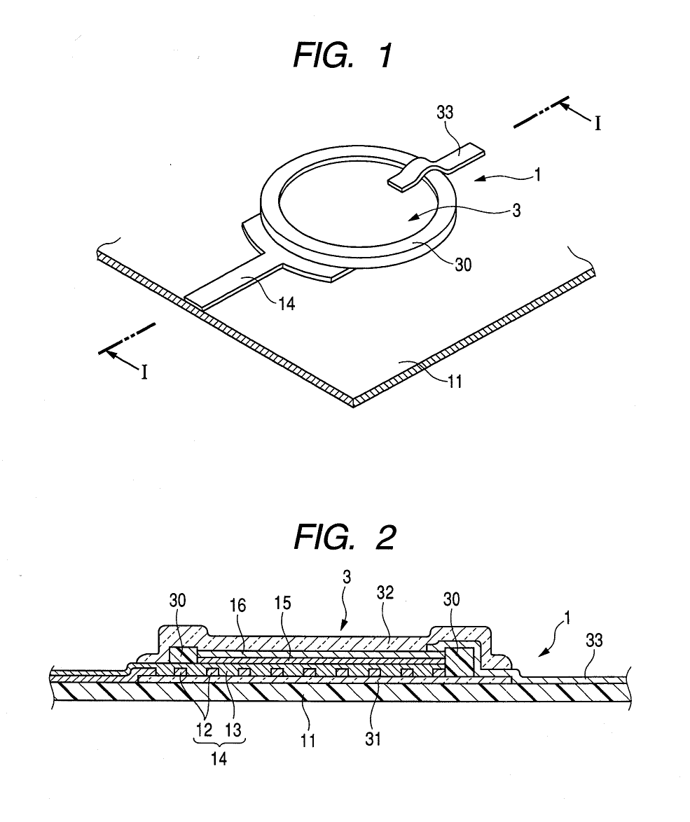

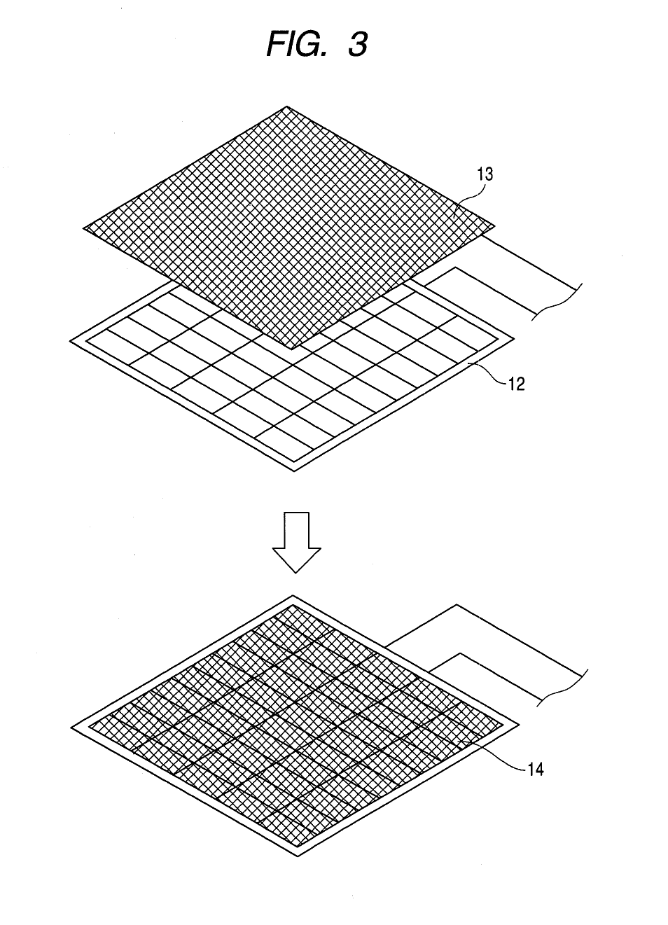

FIG. 1 is a perspective view of a light emitting device 1 according to a first embodiment of the present disclosure. In FIG. 1, sealing layers 31 and 32 are not shown. FIG. 2 is a sectional view taken along the line I-I of FIG. 1, illustrating the light emitting device 1 as seen from the direction of the arrows. FIG. 3 is a schematic perspective view of a transparent electrode layer.

As shown in FIG. 1, the light emitting device 1 of the present embodiment includes a bank (sealing wall) 30 formed in a circular shape on a portion of a substrate 11, a light emitting region 3 disposed within the bank 30 and having a light emitting layer and an electrode layer laminated onto each other, and a sealing layer including a lower sealing layer 31 and an upper sealing layer 32 shown in FIG. 2. When electricity is supplied to the electrode layer from the outside, the light emitting layer emits light and thus the entire light emitting region 3 emits light. The light emitting region 3 is circular because the bank 30 shown in FIG. 1 that surrounds the region 3 is formed in a circular shape. However, the shape of the light emitting region 3 is not particularly limited but may be an ellipse, a triangle, a quadrangle such as a rectangle or a square, or a polygon.

In the present embodiment, as shown in FIG. 2, the lower sealing layer 31 is formed on the surface of the substrate 11. A transparent electrode layer 14 is formed on the lower sealing layer 31, and the bank 30 is formed on the transparent electrode layer 14, defining the light emitting region 3. Within the light emitting region 3 surrounded by the bank 30, the light emitting layer 15 and a counter electrode layer 16 are laminated onto each other to form a light emitting laminated structure. A lead electrode 33 is formed on a portion of the counter electrode layer 16 so as to extend to the outside of the light emitting region 3 across the bank 30. The upper sealing layer 32 seals the entire surface of the light emitting device.

Although the light emitting device shown in FIG. 2 is sealed with two layers of the lower sealing layer 31 and the upper sealing layer 32, the lower sealing layer 31 need not be formed. However, the lower sealing layer 31 enables a secure sealing of the light emitting device. In particular, in the case of the substrate 11 formed of resin, since the resin has poor air-tightness compared with glass, gas such as oxygen or moisture can easily enter the light emitting device through the resin substrate. Thus, by forming the lower sealing layer 31 on the substrate 11, it is possible to prevent entrance of oxygen or moisture and thus to improve sealing properties.

When electricity is supplied to the transparent electrode layer 14 and the lead electrode 33 of the light emitting layer 1, the light emitting layer 15 emits light. The light emitting device 1 of the present embodiment shown in FIG. 2 is a so-called bottom-emission type light emitting device in which the light emitted from the light emitting layer is outputted from the bottom side after passing through the transparent electrode layer 14 and the substrate 11.

Next, materials used in the light emitting device of the present embodiment will be described.

The substrate 11 may be a glass substrate, a resin substrate, or a plastic film. Of them, the plastic film is preferably used as the substrate 11 since it has flexibility. Examples of the resin material of the plastic film or the resin substrate include PET (polyethylene terephthalate), PP (polypropylene), PS (polystyrene), acrylate, polyimide, polyaramid, etc. Of them, PET is particularly preferable in the aspects of transparency, flexibility, and heat resistance. The thickness of the substrate 11 is preferably about 100 μm.

The lower sealing layer 31 is formed on the substrate 11 using glass formed of a silane compound. The glass is produced by a sol-gel method using a metal alkoxide or using a polysilazane compound.

The transparent electrode layer 14 is formed on the lower sealing layer 31. As shown in FIG. 3, the transparent electrode layer 14 has a laminated structure in which the transparent conductive polymer layer 13 is laminated on the mesh-like metal layer 12. As long as the mesh-like metal layer 12 and the transparent conductive polymer layer 13 are laminated onto each other, the transparent electrode layer 14 may have a structure in which the mesh-like metal layer 12 is formed on the transparent polymer layer 13. Alternatively, the transparent electrode layer 14 may have a structure in which the mesh-like metal layer 12 is sandwiched between two layers of the transparent conductive polymer layers 13.

Although the mesh-like metal layer 12 is schematically shown as being individually separated from each other in the sectional view of FIG. 2, the individual metal layers 12 are connected to each other in vertical and horizontal directions in a mesh-like manner.

The metal that forms the mesh-like metal layer 12 can be any metal. Examples of the metal include gold, silver, copper, platinum, aluminum, nickel, indium, yttrium, hafnium, zirconium, magnesium, manganese, vanadium, titan, iron, tungsten, etc. Silver is particularly preferable since it has a high conductivity.

The mesh-like metal layer 12 is formed by printing a metal paste in a mesh shape, the metal paste being obtained by dispersing powder of the above-mentioned metal in a binder solvent.

The particle size of the metal powder is 0.1 to 10 μm. The smaller particle size is preferable since the mesh-like metal layer can be formed as thin as possible. The solvent in which the metal powder is dispersed may be an aquatic solvent or a non-aquatic solvent. For example, water, alcohol or resin may be used.

When the metal paste is applied or printed onto a mesh-like screen and dried thereon, the regular mesh-like metal layer 12 is formed as shown in FIG. 3. An opening ratio (a ratio of the area of a metal-void portion to the entire surface area) of the mesh is 70 to 90%. An opening ratio greater than 99% provides a low conductivity since the total metal amount becomes small, while an opening ratio smaller than 70% provides smaller light emission since transparency becomes poor.

Alternatively, the mesh-like metal layer 12 may be formed by self-organizing the colloidal nano-sized metal particles.

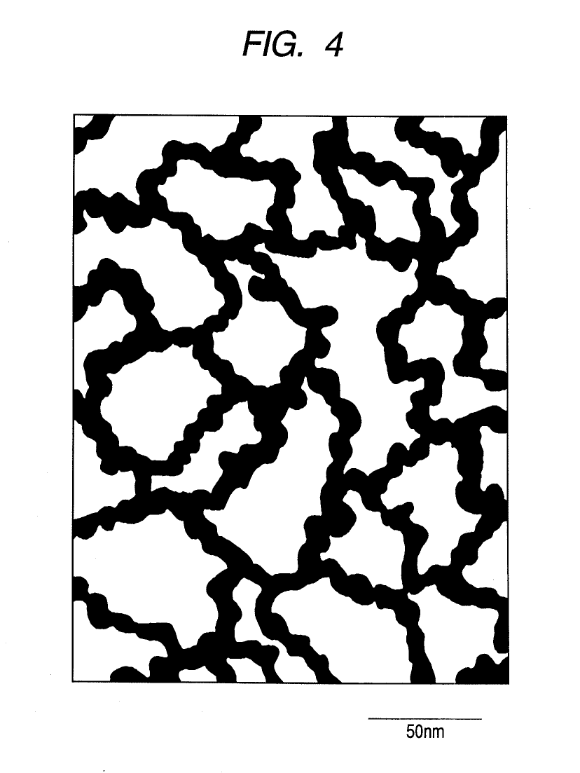

When the colloidal nano-sized metal particles are self-organized, as schematically shown in FIG. 4, a mesh is formed in which a number of metal particles are irregularly connected to each other in a bead shape. Such an irregular mesh-like metal layer may be used as the mesh-like metal layer 12 shown in FIG. 3.

In this case, any metal can be used as a material for the metal layer 12 as long as it can form colloidal nano-sized particles. Gold or silver is preferably used since it has a high conductivity.

When the colloidal nano-sized metal particles are applied so as to be dispersed in a solvent such as water or alcohol, the colloidal nano-sized metal particles are moved toward the vicinity of the solvent. As the solvent volatilizes, the particles disposed in the vicinity of the solvent combine with each other, forming the irregular mesh-like metal layer as shown in FIG. 4.

Since the mesh-like metal layer is obtained by applying and drying the colloidal nano-sized metal particles, it is not necessary to use a mesh-shaped screen as required in the case of printing the metal paste. Thus, the mesh-like metal layer can be formed in an easier manner. Although the mesh shape is irregular since it is obtained by self-organization, the size of the opening (metal-void portion) of the mesh is about 10 to 1000 nm in diameter. Therefore, it is possible to form a mesh-like metal layer having an opening smaller than that for the case of the screen printing method. Accordingly, it is possible to use the mesh-like metal layer in a small light emitting device having an excellent flexibility.

For example, a fiber-like metal layer that is arranged in vertical and horizontal directions in a mesh-like manner may be used as the mesh-like metal layer 12 as long as it is a thin metal film that is arranged in vertical and horizontal direction in a mesh-like manner. Alternatively, one may be used in which a mesh is formed on a metal film or a metal layer. For example, a number of incisions or perforations may be formed in a metal foil and the metal foil is extended in vertical and horizontal direction so as to form a mesh. A number of perforations may be formed in a metal foil to form a mesh shape. Incidentally, the perforations may be formed in the metal foil having metal oxides such as ITO formed thereon. However, patterning the metal oxides such as ITO in a mesh shape requires an etching process after formation of the metal oxides, increasing the production cost.

The method of printing the metal paste in a mesh shape or the method of self-organizing the colloidal nano-sized metal particles is preferable because such a method does not require a process of etching the metal layer to form a mesh thereon and because the metal can be easily formed in a mesh shape using a printing or applying method.

The transparent conductive polymer layer 13 is formed on the mesh-like metal layer 12 using a transparent conductive polymer. The transparent conductive polymer layer 13 is an organic transparent electrode layer that is formed by wet-coating the transparent conductive polymer. A doping agent may be added to the transparent conductive polymer. A transparent conductive polymer solution having a low viscosity is preferably used as a coating solution because it is possible to form the transparent conductive polymer layer in a thin and uniform manner.

The transparent conductive polymer solution is coated on the mesh-like metal layer 12 using a printing or applying method. The transparent conductive polymer solution can be applied using a bar coater, a spray coater, and a roll coater, for example. The transparent conductive polymer solution can be printed using an inkjet printing method, a dispenser printing method, a gravure printing method, and a screen printing method, for example. When the transparent conductive polymer solution is dried under dry air after coating using a printing or applying method, the transparent conductive polymer layer 13 is obtained.

As shown in FIG. 3 or 4, the mesh-like metal layer 12 has a lot of metal-void portions (openings) that are not conductive. However, when a transparent conductive polymer is coated on the mesh-like metal layer 12, the metal-void portions are filled up with the coated transparent conductive polymer. Therefore, the entire surface of the transparent conductive polymer layer 13 becomes conductive. Although uneven surfaces were originally present between the metal portions and the metal-void portions of the mesh-like metal layer 12, because the metal-void portions are filled up with the transparent conductive polymer, flatten the surface of the transparent conductive polymer layer 13. Accordingly, it is possible to form the light emitting layer 15 on the polymer layer 15 in a thin and uniform manner.

The transparent conductive polymer is not particularly limited as long as it is conductive and transparent, but poly-3,4-ethylene dioxythiophene (PEDOT) is particularly preferable. In the case of using PEDOT as the transparent conductive polymer, it is preferable to add polyphenylene sulfide (PPS) as a doping agent.

The thickness of the transparent electrode layer 14 after laminating the transparent conductive polymer layer 13 on the mesh-like metal layer 12 is preferably in the range of about 100 nm to about 10 μm. If the thickness of the transparent electrode layer 14 is smaller than about 100 nm, a voltage applied to the light emitting layer 15 becomes insufficient. Meanwhile, if the thickness of the transparent electrode layer 14 is greater than about 10 μm, the amount of light emitted from the light emitting layer become small. More preferably, the thickness of the transparent electrode layer 14 is in the range of about 200 nm to about 5 μm.

The bank (sealing wall) 30 is formed on the lower sealing layer 31 and the transparent electrode layer 14 in a circular shape by a screen printing method. As shown in FIGS. 1 and 2, a portion of the bank 30 is formed on the transparent electrode layer 14, and another portion of the bank 30 is formed adjacent to the transparent electrode layer 14. A portion of the transparent electrode layer 14 formed inside the bank 30 extends from the lower portion of the bank 30.

Although a material for the bank 30 is not particularly limited as long as it has insulating properties, resin that can be used for a printing method is preferably used, and a thermosetting resist used for fabricating semiconductors is particularly preferable. Although the bank 30 can be made of an opaque material, the bank 30 made of a transparent material can provide a larger amount of light emission to the light emitting device 1 because the light emitted from the light emitting layer, particularly traveling in a horizontal direction can pass through the bank 30.

In the present embodiment, although the bank 30 is formed by the screen printing method, the method is not limited to the screen printing method but may be a printing/coating method such as a spin coating method, an inkjet method, a gravure printing method, or a roll coating method. The height of the bank 30 is substantially equal to or slightly larger than the height of the laminated structure in which the light emitting layer and the electrode layer are laminated onto each other. In the present invention, the height of the bank 30 is set in the range of 1 μm to 20 μm. Further, the bank 30 may be formed of a curable resist layer or may be formed in a wall shape by developing and etching processes.

The light emitting layer 15 is formed on the transparent electrode layer 14 disposed inside the bank 30. The light emitting layer 15 is formed on the entire surface of the light emitting region 3. The light emitting layer 15 is formed by dissolving an organic light emitting material in an organic solvent such as dichloroethane to prepare a solution and applying the solution using an inkjet method or a dispenser, more preferably, a tubing dispenser. In order to shorten the movement distance of electrons and holes, the light emitting layer 15 is preferably made as thin as possible. However, if the light emitting layer 15 is too thin, the light emitting layer 15 can easily short-circuited due to the unevenness formed on the transparent electrode layer 14 below the light emitting layer 15. In the present disclosure, the thickness of the light emitting layer 15 is preferably in the range of about 100 nm to about 200 nm.

Any material can be suitably used as the organic light emitting material as long as it can be used as a so-called organic EL (electro-luminescent) material that spontaneously emits light when receiving external electrical field. Among them, polyfluorene (for example, ADS108G; made by American Dye Source, Inc.), polyphenylenevinylene (for example, ADS100RE; made by American Dye Source, Inc.) and high-molecular light emitting materials are preferably used as the organic light emitting material since they can be dissolved for use in printing process. Alternatively, low-molecular light emitting materials and a mixture of low-molecular light emitting materials and high-molecular light emitting materials are usable. For example, it is possible to use a mixture of polyvinyl carbazole (PVK; a high-molecular hole transporting material), 2,5-bis(1-naphthyl)-1,3,4-oxadiazole (BND; a low-molecular electron transporting material), and 3-(2′-benzothiazolyl)-7-diethylaminocoumarin (coumarin-6; a low-molecular light emitting material). After applying the high-molecular light emitting material, it is preferable to perform a drying process under dry air.

The counter electrode layer 16 is formed on the light emitting layer 15. Similar to the light emitting layer 15, the counter electrode layer 16 is also formed on the entire surface of the light emitting region 3. The counter electrode layer 16 is formed of a conductive metal, for example, gold, silver, copper, platinum, aluminum, nickel, indium, yttrium, hafnium, zirconium, magnesium, manganese, vanadium, titan, iron, tungsten, etc. A metal having a low work function is preferable as the conductive metal since it can lower electron injection energy to increase light emitting efficiency of the organic light emitting layer. In the present embodiment, silver is used as the conductive metal. It is preferable to use a solution in which colloidal nano-sized metal particles are dispersed.

The counter electrode layer 16 is formed by applying a solution in which colloidal nano-sized silver particles dispersed in a solvent onto the light emitting layer 15 and drying the solvent at a predetermined temperature. The colloidal nano-sized silver particles are made by covering the surfaces of nano-sized silver particles whose diameters are equal to or less than several tens of nanometers (less than 100 nm) with a protecting colloid so as to prevent aggregation of the nano-sized silver particles. In a state in which the solution of the colloidal nano-sized silver particles is applied, the colloidal nano-sized silver particles covered with the protecting colloid are dispersed in the solvent. However, when the solvent and the protecting colloid are removed by heating, the nano-sized silver particles remain. When a metallic material, such as silver, is divided into particles having a size of several nanometers, that is, nano-sized particles, the reactivity considerably increases, and thus the particles can combine with each other even at room temperature. Therefore, the nano-sized silver particles obtained by removing the protecting colloid and the solvent are combined with each other to form a very dense and uniform layer. In some portions of the silver layer, a portion of the dispersing agent that has not been dissolved by the heating may remain. However, the concentration of the dispersing agent is very low, and thus it is negligible. Therefore, the remaining dispersing agent does not affect the work function of the counter electrode layer 16.

The protecting colloid, which is a dispersing agent for dispersing the nano-sized silver particles, is preferably a comb-shaped block copolymer. The diameters of the nano-sized silver particles are preferably equal to or less than several tens of nanometers. The average diameter of the nano-sized silver particles is preferably equal to or less than about 20 nm or 10 nm. The solvent, in which the colloidal nano-sized silver particles are dispersed, is preferably water or alcohol, and more preferably, ethanol of alcohol. It doesn't matter if water or alcohol is used as the solvent because the counter electrode layer 16 still has a low work function. In the case of using water as the solvent, even when dried at a low temperature, the counter electrode layer 16 has a low surface resistance. Thus, it is preferable to use water as the solvent.

When water or ethanol, which is the solvent, additionally contains a compound made of alkaline metal, a compound made of alkaline earth metal, an alkaline metal salt, or an alkaline earth metal salt, it is possible to form the counter electrode layer 16 having a low work function. Metals having a low work function are particularly preferable, and examples of the metals include components or salts of cesium, rubidium, potassium, strontium, barium, sodium, calcium, and lithium. For example, any one of potassium acetate, sodium acetate, calcium acetate, lithium acetate, lithium acetylacetonate, calcium acetylacetonate, sodium chloride (NaCl), potassium chloride (KCl), or a combination thereof can be used.

The counter electrode layer 16 is formed by dispersing the colloidal nano-sized silver particles in the solvent to prepare a solution having a silver content in the range of about 10 to about 50% by weight and applying and drying the solution onto the light emitting layer 15. More preferably, the silver content is set to about 30% by weight. When the solution is prepared to have a silver content of about 30% by weight, the content of the dispersing agent, which is a protecting colloid, becomes about 2% by weight.

The prepared solution is dropped onto the light emitting layer 15 using a dispenser, more preferably, a tubing dispenser so as to form a uniform layer. Since the tubing dispenser can flow a very small amount of solution in a non-pulsating manner unlike an air dispenser, it is more preferably used. The thickness of the counter electrode layer 16 before drying is about 40 μm. After performing drying at a predetermined temperature, the counter electrode layer 16 becomes a uniform layer having a thickness of about 1 μm.

The heating temperature when the counter electrode layer 16 is dried is preferably in the range of room temperature to about 200° C. When the heating temperature is higher than about 200° C., in the case of using a resin film or a resin substrate as the substrate 11, deformation easily occurs. When the heating temperature is lower than the room temperature, the drying time is extended, increasing the production time.

The portion on which one or both of the light emitting layer 15 and the counter electrode layer 16 is not formed does not emit light. Therefore, it is preferable to form the counter electrode layer 16 on the entire surface of the light emitting region 3.

The lead electrode 33 is formed on the counter electrode layer 16. The lead electrode 33 is formed by printing, for example, screen-printing a conductive filler and a binder resin. The lead electrode 33 is formed to overlap with a portion of the counter electrode layer 16 and extends to the outside of the light emitting region 3.

Examples of the binder resin include polyester rein, polyethylene resin, polyurethane resin, etc. Any resin appropriate for printing can be preferably used as the binder resin. Examples of the conductive filler are particles of a metal, such as gold, silver, copper, platinum, aluminum, nickel, indium, yttrium, hafnium, zirconium, magnesium, manganese, vanadium, titan, iron, tungsten, etc. Silver that has a low work function is preferably used as the material for the conductive filler.

Because the counter electrode layer 16 formed is dense but thin, the lead electrode 33 may be formed as a protecting layer on the entire surface of the counter electrode layer 16.

After a laminated structure of a light emitting element including the transparent electrode layer 14, the light emitting layer 15, the counter electrode layer 16, and the lead electrode 33 is formed, the laminated structure is sealed with the upper sealing layer 32. The upper sealing layer 32 is formed of glass produced by a sol-gel method using a metal alkoxide or using a polysilazane compound. The lower sealing layer 31 is also formed of glass similar to the upper sealing layer 32.

Metal alkoxide is a compound having at least one M-O—C bond (wherein M is a metal). Suitable examples of a metal alkoxide include aluminum, barium, boron, bismuth, calcium, iron, gallium, germanium, hafnium, indium, potassium, lanthanum, lithium, magnesium, molybdenum, sodium, niobium, lead, phosphorus, antimony, silicon, tin, strontium, tantalum, titanium, vanadium, tungsten, yttrium, zinc, and zirconium. Among them, silica glass can be produced by a sol-gel method, and a metal alkoxide of silicon (silicon alkoxide) is preferable.

Any of the following materials can be used as the silicon alkoxide: tetramethoxysilane, tetraethoxysilane, fluoroalkyl-i-propoxysilane, methyltrimethoxysilane, methyl triethoxysilane, dimethyldiethoxysilane, phenyltriethoxysilane, hexamethyl disilazane, hexyltrimethoxysilane, and decyltrimethoxysilane. Particularly, triethoxysilane, trimethoxysilane, fluoroalkyl, or i-propoxy silane is preferably used.

Among silicon alkoxides, a silane coupling agent having two kinds of functional groups with different reactivities in one molecule can be used. Examples of the silane coupling agent include vinyl trichlorosilane, vinyl trimethoxysilane, vinyl triethoxysilane, 2-(3,4-epoxycyclohexyl)ethyl trimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropylmethyltrimethoxysilane, 3-methacryloxypropylmethyldiethoxysilane, 3-methacryloxypropylmethyltriethoxysilane, 3-acryloxypropylmethyltrimethoxysilane, 3-aminopropylmethyldimethoxysilane, N-2(amino ethyl)-3-aminopropylmethoxysilane, N-2(amino ethyl)-3-aminopropyltrimethoxysilane, 3-aminopropyltrimethoxysilane, 3-aminopropyltriethoxysilane, 3-triethoxysilyl-N-(1,3-dimethylbutylidene)propylamine, N-phenyl-3-aminopropyltrimethoxysilane, hydrochloride of N-(vinylbenzyl)-2-aminoethyl-3-aminopropyltrimethoxysilane, and aminosilane. Particularly, an epoxy group containing one such as 3-glycidoxypropyltrimethoxysilane and 3-glycidoxypropyltriethoxysilane is preferably used.

For example, in the case of using tetraethoxysilane (TEOS) as a metal alkoxide, when TEOS, ethanol, and water are mixed and left as they are, the TEOS decomposes in water, thus forming silanol. Further, a transparent gel of silica is obtained by a dehydration condensation reaction. Then, ethanol and water are evaporated from the obtained gel, and heat treatment is performed at a temperature of 120° C. to 150° C. to obtain glass. The obtained glass is a silica glass, which has gas barrier properties of not transmitting oxygen or moisture. Therefore, it is possible to prevent permeation of oxygen or moisture to the inside of the sealing layer. Instead of ethanol, other alcohol may be used. Also, even when other silicon alkoxide is used, it is possible to obtain silica glass by the same reaction as in the case of TEOS.

In the case of sealing using TEOS, after the laminated structure of the light emitting element including the transparent electrode layer 14, the light emitting layer 15, the counter electrode layer 16, and the lead electrode 33 is formed on the substrate 11, a solution of TEOS is applied using a dispenser, more preferably, a tubing dispenser so as to cover the entire surface of the laminated structure. A solution containing 1% by weight of acetic acid or sulfuric acid is used as the solution of TEOS. After application, heating is performed at a temperature of 100° C. to 200° C., more preferably, 120° C. to 170° C. In this way, glass is produced.

More preferably, as described above, when the lower sealing layer 31 formed of the silica glass produced by the solution of TEOS is formed on the substrate 11, it is possible to seal the entire surface of the light emitting device and thus to improve sealing properties. Since the silica glass has an excellent transparency, it does not interrupt light emission of the light emitting layer 15.

The upper sealing layer 32 may be glass produced by a polysilazane compound. The polysilazane compound is a high-molecular silane compound having a Si—N bond, and perhydropolysilazane (for example, Aquamica NO110; made by AZ Electronic Materials Corp.) may be used as the polysilazane compound.

Perhydropolysilazane reacts with water to produce silica (SiO₂). This reaction occurs in the range of room temperature to about 450° C. Although perhydropolysilazane reacts fast under high temperature or high humidity environments, even at room temperature, it slowly reacts with water in the atmosphere to form silica. The presence of oxygen expedites the reaction. Since perhydropolysilazane reacts with oxygen or water in the atmosphere, it functions as an oxygen- or water-capturing agent.

Similar to the silica glass produced from the metal alkoxide, the silica glass produced by the reaction of perhydropolysilazane is dense and has gas barrier properties of not transmitting oxygen or moisture. Therefore, it is possible to prevent permeation of oxygen or moisture to the inside of the sealing layer. Moreover, since the silica glass has high heat resistance and is transparent, it does not interrupt light emission of the light emitting layer 15 when used as the lower sealing layer 31.

The polysilazane compound can be used as a solution in which the compound is dissolved in an organic solvent such as xylene, dibutylether or terphane. This solution preferably contains a catalyst.

After forming the laminated structure of the light emitting element including the transparent electrode layer 14, the light emitting layer 15, the counter electrode layer 16, and the lead electrode 33, as shown in FIG. 2, a solution containing the polysilazane compound is applied onto the entire surface of the laminated structure using a spray, a disperser or a brush and left as it is. The solution containing the polysilazane compound reacts with moisture or oxygen in the atmosphere to form a dense silica glass. In this case, the reaction may progress quickly if the temperature or the humidity is high. Although the silica glass produced serves as a sealing layer that seals the laminated structure of the light emitting element, since the polysilazane compound reacts with moisture or oxygen that might enter the laminated structure of the light emitting element, the silica glass also functions as a capturing agent during the reaction.

More preferably, by forming on the substrate 11 the lower sealing layer 31 made of glass produced by using the polysilazane compound as described above, it is possible to seal the entire surface of the light emitting device and thus to improve sealing properties. In particular, in the case of using plastic film or resin substrate as the substrate 11, the resin transmits gas such as oxygen or moisture. However, by forming the lower sealing layer 31 on the substrate 11, it is possible to prevent transmission of gas from the substrate 11.

Glass can be produced from the polysilazane compound by using the sol-gel method using the metal alkoxide. As long as the lower sealing layer 31 is made of transparent glass, the lower sealing layer 31 and the upper sealing layer 32 may be formed of any glass. For example, the lower sealing layer 31 may be formed of glass produced from the metal alkoxide while the upper sealing layer 32 may be formed of glass produced from the polysilazane compound. Alternatively, the lower sealing layer 31 may be formed of glass produced from the polysilazane compound while the upper sealing layer 32 may be formed of glass produced from the metal alkoxide. Additionally, both the lower sealing layer 31 and the upper sealing layer 32 may be formed of glass produced from the metal alkoxide, while both the lower sealing layer 31 and the upper sealing layer 32 may be formed of glass produced from the polysilazane compound. Since glass produced from the polysilazane compound has a function of capturing moisture or oxygen, it is more preferable to form the upper sealing layer 32 using the polysilazane compound.

### Second Embodiment

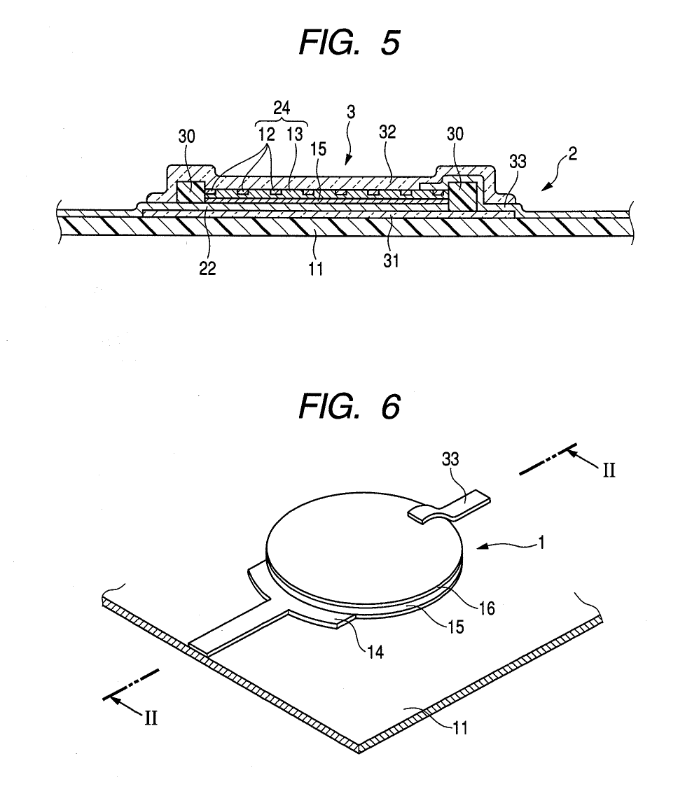

FIG. 5 illustrates a light emitting device according to a second embodiment. The light emitting device of the second embodiment is a so-called top-emission type light emitting device in which the light emitted from the light emitting layer is outputted from the opposite (top) side of a substrate after passing through the transparent electrode layer. Components denoted by the same numeral as those of FIG. 2 are formed of the same materials.

In the second embodiment, the lower sealing layer 31 made of glass is formed on the substrate 11, and the lower electrode layer 22 is formed on the lower sealing layer 31. Since the light emitted from the light emitting device is outputted from the top side thereof, the substrate 11 needs not be transparent. The lower electrode layer 22 is formed of a solution in which colloidal nano-sized metal particles are dispersed, similar to the case of the counter electrode layer 16. Moreover, since the metal layer formed of the colloidal nano-sized metal particles is dense and thin, a conductive filler and a binder resin may be printed thereon before applying colloidal nano-sized metal particles on the metal layer.

The bank 30 is formed on the lower electrode layer 22 or the lower sealing layer 31, defining the light emitting region 3. The light emitting layer 15 and the transparent electrode layer 24 are additionally formed on the lower electrode layer 22 disposed within the light emitting region 3.

The transparent electrode layer 24 is composed of the transparent conductive polymer layer 13 that is formed on the light emitting layer 15 and the mesh-like metal layer 12 that is formed on the transparent conductive polymer layer 13. The transparent electrode layer may be configured such that the transparent conductive polymer layer 13 is additionally formed on the mesh-like metal layer 12 so that the mesh-like metal layer is sandwiched between the transparent conductive polymer layers.

The lead electrode 33 is formed to overlap with a portion of the transparent electrode layer 24. The lead electrode 33 extends to the outside of the bank 30 across the bank 30.

A laminated structure of the light emitting element including the lower electrode layer 22, the light emitting layer 15, the transparent electrode layer 24, and the lead electrode 33 is sealed with the upper sealing layer 32. The upper sealing layer 32 and the lower sealing layer 31 are formed of glass produced by a sol-gel method using a metal alkoxide or using a polysilazane compound.

Similar to the first embodiment, the lower sealing layer 31 need not be formed. The lower sealing layer 31 and the upper sealing layer 32 may be formed of glass produced by a sol-gel method using a metal alkoxide or of glass produced from a polysilazane compound.

### Third Embodiment

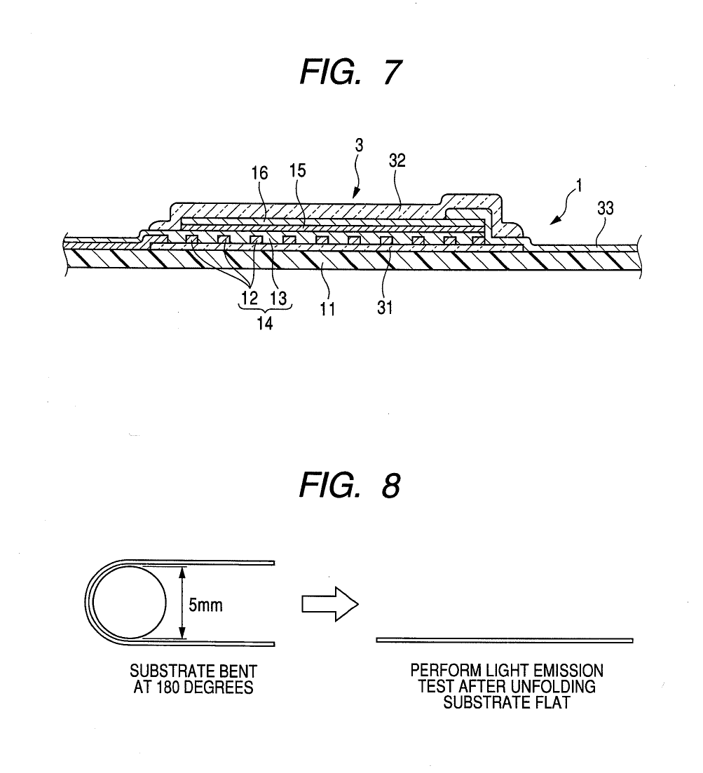

FIG. 6 illustrates a light emitting device according to a third embodiment. FIG. 7 is a sectional view taken along the line II-II of FIG. 6, illustrating the light emitting device as seen from the direction of the arrows.

In the third embodiment, the bank 30 shown in FIG. 1 is not formed, and the surface of a laminated structure of the light emitting layer and the electrode layer serves as the light emitting region 3. The light emitting device of the third embodiment is a bottom-emission type light emitting device similar to the first embodiment. Components denoted by the same numeral as those of FIGS. 1 and 2 are formed of the same materials.

The lower sealing layer 31 and the transparent electrode layer 14 composed of the mesh-like metal layer 12 and the transparent conductive polymer layer 13 are formed on the substrate 11. Next, the light emitting layer 15 and the counter electrode layer 16 are formed on the transparent electrode layer 14 without forming the bank. The lead electrode 33 is formed to overlap with a portion of the counter electrode layer 16. The upper sealing layer 32 seals the entire surface of the light emitting device.

The bank is not formed in the present embodiment. However, light is emitted from the portion where the transparent electrode layer 14, the light emitting layer 15 and the counter electrode layer 16 are overlapped with each other. The portion serves as the light emitting region. Light is not emitted from the portions on which any one of the transparent electrode layer 14, the light emitting layer 15 and the counter electrode layer 16 is not formed. Therefore, it is preferable to align the overlapping portions of the transparent electrode layer 14, the light emitting layer 15 and the counter electrode layer 16 with high precision and with the same shapes.

In FIG. 6, the overlapping portions of the transparent electrode layer 14, the light emitting layer 15 and the counter electrode layer 16 are circular. However, the shape of the overlapping portions is not limited to the circular shape but may be an ellipse, a triangle, a quadrangle such as a rectangle or a square, or a polygon, in a similar manner to the case of forming the bank 30.

Similar to the case of the third embodiment, the bank 30 may not be provided in the top-emission type light emitting device of the second embodiment.

### EXAMPLE

Hereinafter, examples of the present invention will be described, but the present invention is not limited thereto.

### Example 1

The light emitting device shown in FIGS. 1 and 2 was produced in the following processes.

A transparent PET film (Lumirror U94; made by Toray industries Inc.) having a thickness of 100 μm was used as the substrate 11, and a mesh-like silver electrode layer 12 was formed on the substrate 11 by a printing method using a silver paste in which silver particles are dispersed in a solvent.

Specifically, the silver paste used was LS-415-NF3 (made by Asahi Chemical Research Laboratory Co., Ltd.) in which silver particles are dispersed in a polyester resin binder. Screen printing was performed on the substrate 11 using a 400-mesh stainless screen printing plate. Then, a heating process was performed under dry air at a temperature of 140° C. for fifteen minutes. In this way, the mesh-like metal layer 12 was formed.

The transparent conductive polymer layer 13 was formed on the mesh-like metal layer 12. Specifically, PEDOT/PSS (TYPE EL-P5020; made by Agfa-Gevaert Group) was used as the transparent conductive polymer. Screen printing was performed on the mesh-like metal layer 12 using a 250-mesh polyester screen printing plate. Then, a heating process was performed under dry air at a temperature of 140° C. for fifteen minutes. In this way, the transparent conductive polymer layer 13 was formed to fill up the concave portions of the mesh-like metal layer, flattening the surface of the transparent conductive polymer layer 13.

Subsequently, the bank (sealing wall) 30 was formed by screen printing so as to define a circular light emitting region 3 (having a diameter of 5 mm to 10 mm). Specifically, the bank 30 was formed of a thermosetting transparent resist for a flexible circuit (CR-18G-KT1; made by Asahi Chemical Research Laboratory Co., Ltd.). Screen printing was performed using a 200-mesh stainless screen printing plate. Then, a heating process was performed under dry air at a temperature of 140° C. for fifteen minutes.

Subsequently, the light emitting layer 15 was formed on a portion of the transparent conductive polymer layer 13 surrounded by the bank 30. Specifically, the organic light emitting material used was obtained by mixing PVK (polyvinyl carbazole), BND (2,5-bis(1-naphthyl)-1,3,4-oxadiazole), and coumarin-6 (3-(2′-benzothiazolyl)-7-diethylaminocoumarin) at a weight ratio of 160:40:1 and dissolving the mixture in a solvent of dichloroethane so that the content becomes 2% by weight of the solvent. PVK, END, and coumarin-6 serve as a hole transport material, an electron transport material, and a light emitting material, respectively.

A solution of the organic light emitting material was dropped onto a portion disposed within the bank 30 using a tubing dispenser, and a heating process was performed under dry air at a temperature of 140° C. for fifteen minutes.

Subsequently, the counter electrode layer 16 was formed on the light emitting layer 15. Specifically, colloidal nano-sized silver ink (Fine Sphere SVW102; made by Nippon Paint Co., Ltd.) was dropped onto the light emitting layer using a tubing dispenser. Then, a heating process was performed under dry air at a temperature of 140° C. for fifteen minutes. In this way, the counter electrode layer 16 was formed. The average diameter of the silver particles was about 10 nm, and a solvent of the colloidal ink was water.

Subsequently, the lead electrode 33 was formed to overlap with a portion of the counter electrode layer 16 using a silver paste. The silver paste used was the same as that used for forming the mesh-like metal layer 12. The lead electrode 33 was formed to have a predetermined wiring pattern by screen printing so as to extend from a portion of the counter electrode layer 16 to the outside of the layer 16 across the bank 30.

Subsequently, the upper sealing layer 32 was formed using glass produced from a polysilazane compound so as to cover the bank 30 and the portion disposed within the bank 30. Specifically, as shown in FIG. 2, the upper sealing layer 32 was not formed on portions of the transparent electrode layer 14 and the lead electrode 33.

A solution containing perhydropolysilazane (Aquamica NP110; made by AZ Electronic Materials Corp.) was applied to cover the bank 30 and the portion disposed within the bank 30 using a tubing dispenser and was left as it was, forming the upper sealing layer 32 made of glass.

When a voltage of 20 V was applied to the transparent electrode layer 14 (anode) and the counter electrode layer 16 (cathode) of the light emitting device obtained by the above-mentioned processes, green light with a brightness of 20 cd (candela)/m² was emitted.

### Example 2

The light emitting device shown in FIGS. 1 and 2 was produced in the same manner as Example 1 except that the mesh-like metal layer 12 was formed by self-organization of colloidal nano-sized metal particles.

The colloidal nano-sized metal particles used were colloidal nano-sized gold-silver ink (transparent conductive pigment (Au—Ag ink); made by Sumitomo Metal Mining Co., Ltd.). The ink was applied on the substrate using a tubing dispenser. A heating process was performed under dry air at a temperature of 120° C. for fifteen minutes. The dried substrate was transparent. TEM observation showed that nano-sized gold-silver particles were arranged in a mesh shape, as shown in FIG. 4.

The light emitting device was produced in the same manner as Example 1 except for the mesh-like metal layer 12. When a voltage of 20 V was applied to the transparent electrode layer 14 (anode) and the counter electrode layer 16 (cathode) of the light emitting device, green light with a brightness of 10 cd (candela)/m² was emitted.

### Example 3

The light emitting device shown in FIGS. 1 and 2 was produced in the same manner as Example 1 except that the transparent conductive polymer layer 13 was formed using a low-viscosity solution.

The transparent conductive polymer used was PEDOT/PSS (Orgacon S-300; made by Agfa-Gevaert Group). The transparent conductive polymer was applied using a bar coater. Then, a heating process was performed under dry air at a temperature of 140° C. for fifteen minutes. Orgacon S-300 (made by Agfa-Gevaert Group) used had a viscosity lower than that of TYPE EL-P5020 used in Example 1. Thus, it was possible to obtain the transparent conductive polymer layer 13 with a smaller thickness.

Similar to the case of Example 1, the light emitting device produced had emitted green light with a brightness of 10 cd (candela)/m².

### Comparative Example 1

The light emitting device shown in FIGS. 1 and 2 was produced in the same manner as Example 1 except that ITO was used instead of the mesh-like metal layer 12.

The substrate used was a commercially available ITO-coated PET film (Toray HighBeam NX01) which is obtained by forming ITO film on the substrate. The same PEDOT/PSS (TYPE EL-P5020; made by Agfa-Gevaert Group) as that used in Example 1 was screen-printed on the ITO of the ITO-coated PET film using a 250-mesh polyester screen printing plate. In this way, the transparent conductive polymer layer 13 was formed, and the transparent electrode layer 14 was prepared. Thereafter, in a manner similar to Example 1, the bank 30, the light emitting layer 15, the counter electrode layer 16, the lead electrode 33, and the upper sealing layer 32 were formed.

When a voltage of 20 V was applied to the transparent electrode layer 14 (anode) and the counter electrode layer 16 (cathode) of the light emitting device obtained by the above-mentioned processes, green light with a brightness of 20 cd (candela)/m² was emitted.

A sheet resistance of the transparent electrode layer 14, formed in Example 1, composed of the mesh-like metal layer 12 and the transparent conductive polymer layer 13 was measured to be 1.5Ω/□. On the other hand, a sheet resistance of the transparent electrode layer 14, formed in Comparative Example 1, obtained by forming the transparent conductive polymer layer 13 on the ITO-coated PET film was measured to be 100Ω/□, which was higher than that of the transparent electrode layer of the present invention.

The light emitting device of Example 1 provided light emission with a brightness about half of the brightness (10 cd/m² at application voltage of 20 V) provided by the light emitting device of Comparative Example 1 that had the transparent electrode using ITO.

Next, flexibility of the light emitting device was tested.

The substrate having the light emitting device of Example 1 formed thereon and the substrate having the light emitting device of Comparative Example 1 were bent at 180 degrees about a circular rod with a diameter of 5 mm as shown in FIG. 8, and a light emission test was performed on the substrates in a state that the substrates were unfolded flat. Such an operation was performed repeatedly.

Uneven light emission was found on several places of the light emitting device of Example 1 after the bending operation was performed for thousand times, but the light emitting device still emitted light.

On the other hand, uneven light emission was found on the light emitting device of Comparative Example 1 after the bending operation was performed for two times, but the light emitting device stopped light emission after the bending operation was performed for ten times.

Performance test results of the light emitting devices of Example 1 and Comparative Example 1 are shown in Table 1

TABLE 1

| | | Sheet | | |
|---|---|---|---|---|
| | | Resistance | | |
| | | Of Anode | Device | |
| | Transparent | Electrode | Brightness | |
| | Electrode | (Ω/□) | (cd/m²) | Flexibility |
| Example 1 | Mesh-like Ag | 1.5 | 10 | Uneven light |
| | Electrode + | | | emission found |
| | PEDOT/PSS | | | after bending for |
| | | | | 1000 times |
| Compara- | ITO + | 100 | 20 | Uneven light |
| tive | PEDOT/PSS | | | emission found |
| Example 1 | | | | after bending for |
| | | | | 2 times (light |
| | | | | emission stopped |
| | | | | after bending for |
| | | | | 10 times) |

As can be seen from Table 1, the light emitting device of the present invention had an excellent flexibility with the sacrifice of the brightness of light emission about half of the brightness provided by the light emitting device that had the transparent electrode using ITO.

The terms and descriptions used herein are set forth by way of illustration only and are not meant as limitations. Those skilled in the art will recognize that many variations can be made to the details of the above-described embodiments without departing from the underlying principles of the disclosure. The scope of the disclosure should therefore be determined only by the following claims (and their equivalents) in which all terms are to be understood in their broadest reasonable sense unless otherwise indicated

1. A light emitting device in which a transparent electrode layer, an organic light emitting layer and a counter electrode layer are laminated in this order on a transparent substrate,
wherein the transparent electrode layer is formed of mesh-like metal material and a transparent conductive polymer.

2. A light emitting device in which a lower electrode layer, an organic light emitting layer and a transparent electrode layer are laminated in this order on a substrate,
wherein the transparent electrode layer is formed of mesh-like metal material and a transparent conductive polymer.

3. The light emitting device according to claim 1, wherein a light emitting region surrounded by a bank is formed on the transparent substrate or the transparent electrode layer, and the transparent electrode layer, and the organic light emitting layer and the counter electrode layer are formed inside the light emitting region.

4. The light emitting device according to claim 2, wherein a light emitting region surrounded by a bank is formed on the substrate or the lower electrode layer, and
the lower electrode layer, the organic light emitting layer and the transparent electrode layer are formed inside the light emitting region.

5. The light emitting device according to claim 1, wherein the mesh-like metal material are formed by printing a solution in which metal particles are dispersed in a solvent.

6. The light emitting device according to claim 1, wherein the mesh-like metal material is obtained by arranging nano-sized metal particles in a mesh shape.

7. The light emitting device according to claim 1, wherein the metal is silver.

8. The light emitting device according to claim 1, wherein the counter electrode layer or the lower electrode layer is a silver layer formed of colloidal nano-sized silver particles.

9. The light emitting device according to claim 1, wherein the substrate or the transparent substrate is a resin film or a resin substrate.

10. A method of producing a light emitting device using an organic light emitting layer, the method comprising the steps of:
(a) printing a solution in which metal particles are dispersed in a solvent in a mesh shape on a transparent substrate so as to form a mesh-like metal layer on the transparent substrate;
(b) forming a transparent conductive polymer layer on the mesh-like metal layer;
(c) forming an organic light emitting layer on the transparent conductive polymer layer; and
(d) forming a counter electrode layer on the organic light emitting layer.

11. A method of producing a light emitting device using an organic light emitting layer, the method comprising the steps of:
(a) forming a lower electrode layer;
(b) forming an organic light emitting layer on the lower electrode layer;
(c) forming a transparent conductive polymer layer on the organic light emitting layer; and
(d) printing a solution in which metal particles are dispersed in a solvent in a mesh shape on the transparent conductive polymer layer so as to form a mesh-like metal layer on the transparent conductive polymer layer.

12. A method of producing a light emitting device using an organic light emitting layer, the method comprising the steps of:
(a) applying and drying nano-sized metal particles on a transparent substrate so as to form a mesh-like metal layer on the transparent substrate.
(b) forming a transparent conductive polymer layer on the mesh-like metal layer;
(c) forming an organic light emitting layer on the transparent conductive polymer layer; and
(d) forming a counter electrode layer on the organic light emitting layer.

13. A method of producing a light emitting device using an organic light emitting layer, the method comprising the steps of:
(a) forming a lower electrode layer;
(b) forming an organic light emitting layer on the lower electrode layer;
(c) forming a transparent conductive polymer layer on the organic light emitting layer; and
(d) applying and drying nano-sized metal particles on the transparent conductive polymer layer so as to form a mesh-like metal layer on the transparent conductive polymer layer.

14. The method of producing a light emitting device according to claim 10, further comprising,
(e) after step (b), forming a bank on the transparent substrate or the transparent conductive polymer layer so as to surround a light emitting region,
wherein the organic light emitting layer and the counter electrode layer are formed on the light emitting region.

15. The method of producing a light emitting device according to claim 11, further comprising,
(e) after step (a), forming a bank on the substrate or the lower electrode layer so as to surround a light emitting region,
wherein the organic light emitting layer, the transparent conductive polymer layer and the mesh-like metal layer are formed on the light emitting region.
